(19) United States
(12) Patent Application Publication
(10) Pub. No.: US 2020/0053261 A1
(43) Pub. Date: Feb. 13, 2020

(54) DISPLAY APPARATUS AND ELECTRONIC EQUIPMENT

(71) Applicant: SHARP KABUSHIKI KAISHA, Osaka (JP)

(72) Inventor: JUNYA TAKAHASHI, Osaka (JP)

(21) Appl. No.: 16/527,976

(22) Filed: Jul. 31, 2019

(30) Foreign Application Priority Data
Aug. 7, 2018 (JP) 2018-148601

(51) Int. Cl. H04N 5/225; H05K 5/00

(52) U.S. Cl. CPC H04N 5/2257; H01L 27/32; H04N 5/2253; H05K 5/0017

(57) ABSTRACT

A display apparatus includes a display element which faces a screen and in which an opening that allows transmission of light from outside, which has passed through the screen, is formed. A device that inputs and outputs information to electronic equipment is fixed to the display element through a fixing member, which is installed on the display element, so that the device is able to receive the light transmitted through the opening.

### BACKGROUND

### 1. Field

The present disclosure relates to a display apparatus and electronic equipment.

### 2. Description of the Related Art

A mobile phone or the like has a device, such as a camera module, installed between a display screen and a housing, for example, in order for a user to make a call while seeing a face of a called party. Thus, in the display screen, an opening through which light is transmitted is formed at a position where the device is provided.

Japanese Unexamined Patent Application Publication No. 2012-70356 (published on Apr. 5, 2012) discloses a method of installing a sensor on a back side of a display screen such as an organic Electro Luminescence (EL) display to visually obscure the sensor when viewed from a front side of the display screen.

In the related art as described above, however, when a display screen and a substrate or the like are installed, a positional shift is caused between the opening formed in the display screen and the device attached to the substrate or the like. Factors of causing the shift are as follows: (i) the shift is caused when the device is attached to the substrate or the like, and (ii) the shift is caused when the substrate or the like and the display screen are installed.

Thus, the opening is formed with a large size in consideration of the positional shift caused between the device and the opening when the substrate or the like and the display screen are installed. Therefore, there is a possibility that the opening is visually noticed and design of the display screen is spoiled.

In an aspect of the disclosure, by reducing a size of an opening formed in a display screen, design of the display screen is enhanced.

### SUMMARY

To cope with the aforementioned problem, a display apparatus according to an aspect of the disclosure has a configuration in which the display apparatus is provided in electronic equipment, and includes a display element which faces a screen that allows transmission of light and in which at least one opening that allows transmission of the light from outside, which has passed through the screen, is formed. A device that inputs and outputs information to the electronic equipment is fixed to the display element through a fixing member, which is installed on the display element, so that the device is able to receive the light transmitted through the opening.

To cope with the aforementioned problem, electronic equipment according to an aspect of the disclosure has a configuration in which the electronic equipment includes at least one display apparatus. The display apparatus includes a display element which faces a screen that allows transmission of light and in which at least one opening that allows transmission of the light from outside, which has passed through the screen, is formed, and a device that inputs and outputs information to the electronic equipment is fixed to the display element through a fixing member, which is installed on the display element, so that the device is able to receive the light transmitted through the opening.

### Advantageous Effects of Invention

An aspect of the disclosure advantageously provides, for example, a display apparatus in which design of the display screen is enhanced by reducing a size of an opening formed in a display screen.

### BRIEF DESCRIPTION OF THE DRAWINGS

FIG. 1 is a schematic view of a display apparatus according to Embodiment 1 of the disclosure;

FIG. 2A is a schematic view illustrating an example of an appearance of a holder and FIG. 2B is a schematic view illustrating an example of the changed appearance of the holder;

FIG. 3A is a perspective view when a device is installed in electronic equipment according to Embodiment 1 of the disclosure and FIG. 3B is a side view when the device is installed in the electronic equipment according to Embodiment 1 of the disclosure;

FIG. 4A is a schematic view of the display apparatus according to Embodiment 1 of the disclosure as viewed from a surface of a display element, which faces a screen, and FIG. 4B is a schematic view of the display apparatus in a state where the device of FIG. 4A is illustrated as being transparent;

FIG. 5 is a schematic view of a display apparatus according to Embodiment 2 of the disclosure; and

FIG. 6 is a schematic, view of a display apparatus according to Embodiment 3 of the disclosure.

### DESCRIPTION OF THE EMBODIMENTS

### Embodiment 1

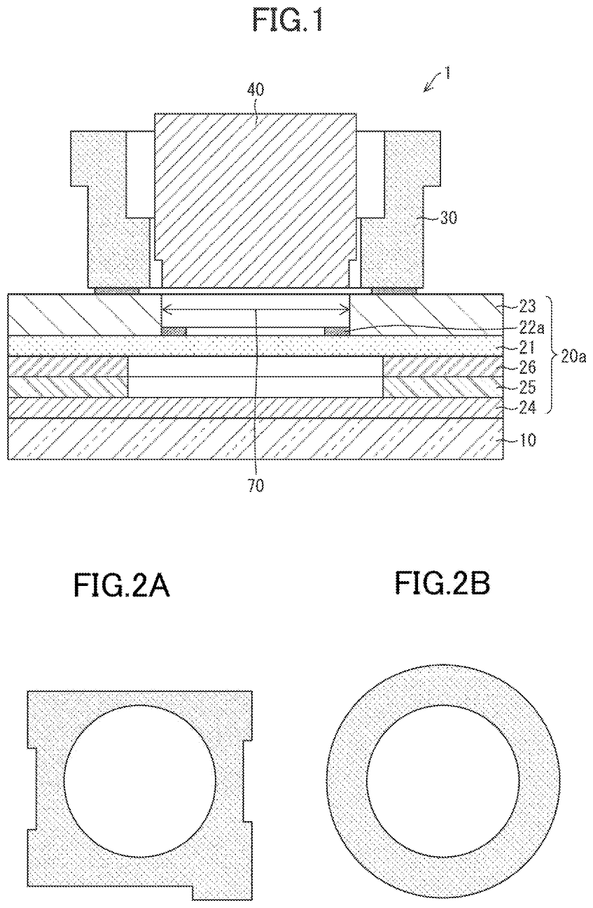

An embodiment of the disclosure will be described in detail below with reference to FIGS. 1 to 4B. (Outline of display apparatus)

An outline of a display apparatus 1 according to Embodiment 1 of the disclosure will be described with reference to FIG. 1. FIG. 1 is a schematic view of the display apparatus 1.

The display apparatus 1 includes a screen 10, a display element 20a, a fixing member: 30, and a device 40.

The screen 10 is formed of a material, such as glass or resin, through which light is transmitted, and forms an outermost surface of the display apparatus 1.

The display element 20a is a liquid crystal display element and is provided so as to contact the screen 10 in an opposed manner. A liquid crystal display element is used as the display element 20a in the display apparatus 1 according to Embodiment 1.

The display element 20a includes at least a liquid crystal panel 21 and a backlight 23. In addition to the liquid crystal panel 21 and the backlight 23, the display element 20a may include members, such as a touch panel 24, an optical clear adhesive (OCA) tape 25, and a polarizer 26, which form the liquid crystal display element as illustrated in FIG. 1.

At least one opening 70 is formed in the display element 20a. The opening 70 is formed as a path in which light is transmitted to the screen 10 and the device 40 which is described below. Thus, as long as the device 40 described below is able to receive light transmitted through the screen 10, a hole may be formed to penetrate through the display element 20a as the opening 70 or the opening 70 may be covered with a part of the display element 20a. Note that, in the display apparatus 1 according to Embodiment 1, the opening 70 is partially covered with the liquid crystal panel 21.

A print (print for positioning) 22a used to position the device 40 and the display element 20a may be formed in the opening 70. A shape and a color of the print 22a are not limited as long as the device 40 and the display element 20a are able to be positioned. Note that, though the print 22a is provided on the liquid crystal panel 21 in the display apparatus 1 according to Embodiment 1, the print 22a is able to be freely provided in the display element 20a, the screen 10, or the like.

The fixing member 30 is a member by which the device 40 is fixed to the display element 20a through the fixing member 30. Note that, though a holder is used as the fixing member 30 in the display apparatus 1 according to Embodiment 1, a sheet or the like having an adhesive property is also able to be used. In addition, the fixing member 30 is able to be used alone or a plurality of fixing members 30 are able to be used in combination.

An example of the fixing member 30 is illustrated in FIGS. 2A and 2B. In FIG. 2A, the fixing member 30 has a circular opening formed in a center thereof and has an appearance in a substantially rectangular shape as viewed from an opening surface side. In FIG. 2B, the fixing member 30 has a circular opening formed in the center thereof and has the appearance in a circular shape as viewed from the opening surface side. The shape of the opening formed in the center of the fixing member 30 is not limited to the circular shape and is able to be changed to an elliptical shape, a rectangular shape, or the like in accordance with a shape of the device 40 or the like. Further, the shape of the appearance of the fixing member 30 is not particularly limited and is able to be changed freely.

The device 40 is fixed to the display element 20a through the fixing member 30 so that the device 40 is able to receive light which is radiated from outside and transmitted through the screen 10 and the opening 70. Alternatively, the device 40 is fixed to the display element 20a through the fixing member 30 so that the device 40 is able to output light to the outside through the opening 70 and the screen 10. By fixing the device 40 to the display element 20a, it is possible to substantially fix a position where the device 40 is installed relative to the opening 70. Further, for example, assumed is a case where the device 40 is fixed to the display element 20a and the display element 20a is then installed in the display apparatus 1. Since the device 40 is fixed to the display element 20a, the position where the device 40 is installed is not shifted. As a result, a substantially fixed positional relationship between the opening 70 and the display element 20a is able to be kept, and therefore, the opening 70 is not requested to have a size set in consideration of the shift of the installation position. This makes is possible to reduce the size of the opening 70 and the opening 70 becomes visually obscure. The reduction of the size of the opening 70 enables enhancement of design of a display screen.

In addition, a bonding apparatus is also able to be used to fix the device 40 to the display element 20a. In an example of bonding the; device 40 to the display element 20a by using the bonding apparatus, the device 40 is fixed so that an outer periphery of the circular opening formed in the center of the fixing member 30 and an inner circle of the print 22a for positioning, which is formed in an annular shape, appear to be overlapped with each other. By bonding the device 40 and the display element 20a as described above, the position where the device 40 is installed on the display element 20a is able to be substantially fixed. Thus, use of the bonding apparatus makes it possible to suppress the shift of the position where the device 40 is installed on the display element 20a. (An installation example of camera module)

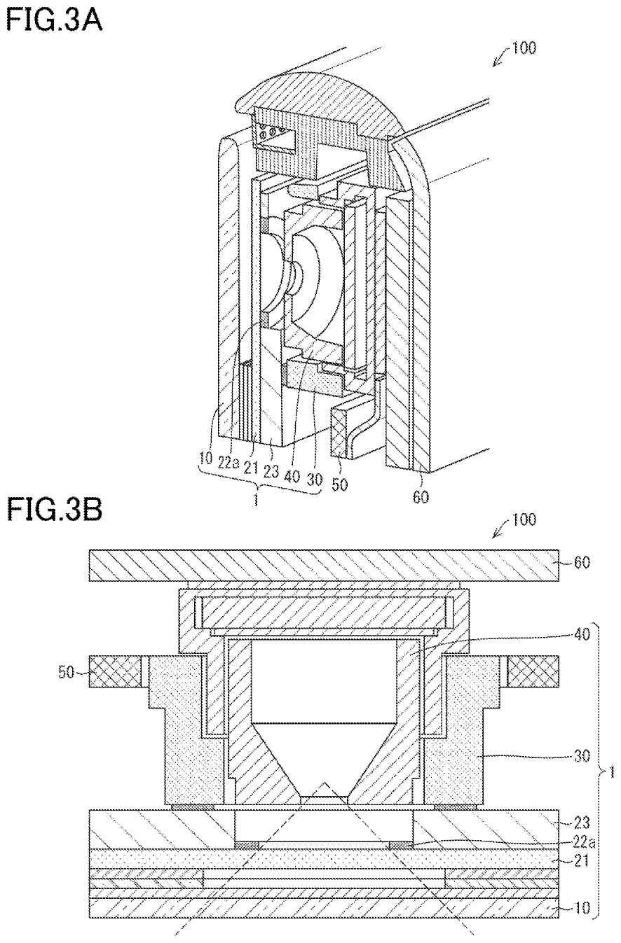

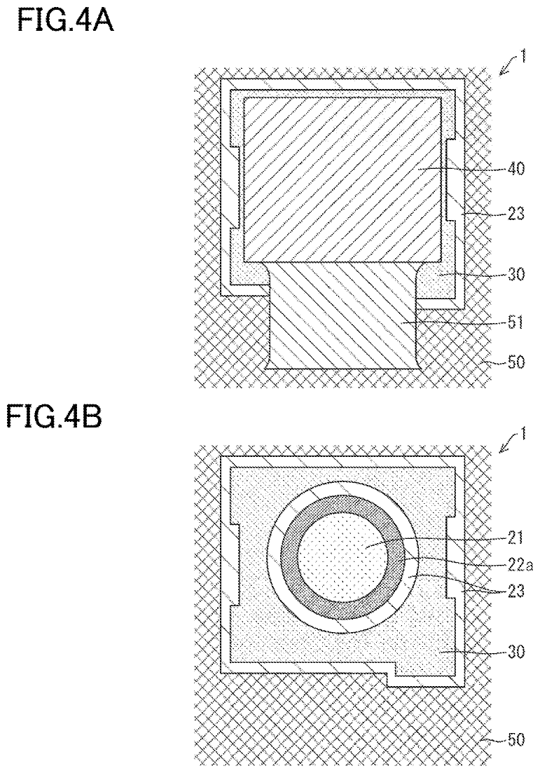

An installation example when a camera module is used as the device 40 is illustrated in FIGS. 3A, 3B, 4A, and 4B. FIG. 3A is a perspective view of electronic equipment 100 according to Embodiment 1 of the disclosure; when the device 40 is installed in the electronic equipment 100. FIG. 3B is a side view of the electronic equipment 100 according to Embodiment 1 of the disclosure when the device 40 is installed in the electronic equipment 100. FIG. 4A is a schematic view of the display apparatus 1 according to Embodiment 1 of the disclosure as viewed from a surface of the display element 20a, which faces the screen 10 and FIG. 4B is a schematic view of the display apparatus 1 in a state where the device 40 of FIG. 4A is illustrated as being transparent. Note that, the camera module is used as the device 40.

The device 40 is fixed by the fixing member 30 so that a lens of the device 40 faces toward the backlight 23 in a notch formed in a main substrate 50. Note that, though FIGS. 4A and 4B each illustrate the notch in a substantially rectangular shape, the shape of the notch is not particularly limited.

As illustrated in FIGS. 3A and 3B, the device 40 is fixed to the backlight 23 through the fixing member 30. The device 40 is arranged at a position held between the backlight 23 and a housing 60. At this time, the device 40 may contact or may not contact the housing 60, FIGS. 3A and 3B each illustrate a state where the device 40 contacts the housing 60. However, since the device 40 is fixed to the backlight 23 through the fixing member 30, even when the device 40 contacts the housing 60, a position where the device 40 is fixed relative to the opening 70 does not change.

Moreover, as illustrated in FIG. 4A, the device 40 is connected to the main substrate 50 through a camera flexible part 51. Note that, a print 22a may be formed in a doughnut-shape in the opening 70 of the fixing member 30 and on the liquid crystal panel 21 as illustrated in FIG. 4B and may be formed by a dot or the like so as to indicate only the installation position.

Moreover, as the electronic equipment 100 including the display apparatus 1 according to the present embodiment, in addition to a smartphone exemplified below, a foldable mobile phone, a wearable terminal, a small-sized game machine, a tablet terminal, and the like are able to be exemplified. In other words, the electronic equipment 100 to which the disclosure is to be applied is not limited as long as including the display apparatus 1 in which the device 40, such as the camera module, which captures an image through the display screen is installed. Further, as the display element 20a, in addition to the liquid crystal display element, an organic EL display element, an organic light emitting diode display element, or the like is able to be used for the electronic equipment 100. In addition, the device 40 is not limited as long as being a device that inputs and outputs information to the electronic equipment 100 and examples thereof include, in addition to the camera module, a proximity sensor and a light emitting device such as an Light Emitting Diode (LED) light. The electronic equipment 100 may include a plurality of different types of devices 40.

### Embodiment 2

Another embodiment of the disclosure will be described below. Note that, for convenience of description, members having the same functions as those of the members described in the embodiment described above will be given the same reference signs and description thereof will not be repeated.

A display apparatus 2 according to Embodiment 2 of the disclosure is illustrated in FIG. 5. The display-apparatus 2 according to the present embodiment is different from the display apparatus 1 of Embodiment 1 described above in that an organic EL display element is used as a display element 20b. Thus, as illustrated in FIG. 5, the display apparatus 2 according to the present embodiment includes, as the display element 20b, the OCA tape 25, a transparent display device 27, and the opening 70, and has a device 41 fixed to a print 22b. Note that, the print 22b is formed on the transparent display device 27. A configuration other than the configuration described above is similar to that of the display apparatus 1 of Embodiment 1. Note that, similarly to the display element 20a of the display apparatus 1 of Embodiment 1 described above, the display element 20b may include the touch panel 24, the polarizer 26, and the like in addition to the OCA tape 25 and the transparent display device 27.

### Embodiment 3

Another embodiment of the disclosure will be described below. Note that, for convenience of description, members having the same functions as those of the members described in the embodiments described above will be given the same reference signs and description thereof will not be repeated.

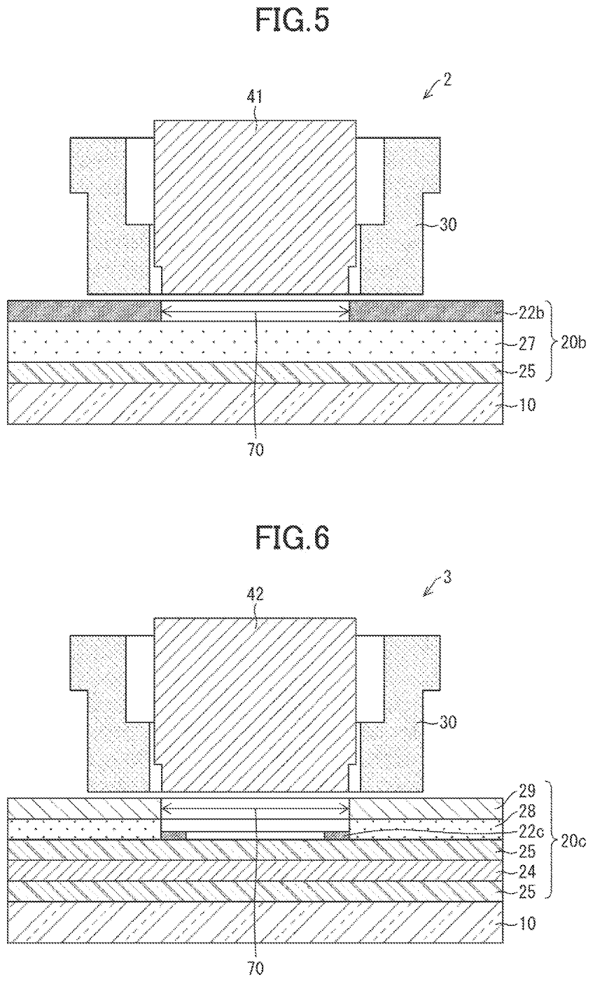

A display apparatus 3 according to Embodiment 3 of the disclosure is illustrated in FIG. 6. The display-apparatus 3 according to the present embodiment is different from the display apparatus 1 of Embodiment 1 described above in that an organic light emitting diode display element is used as a display element 20c. Thus, as illustrated in FIG. 6, the display apparatus 3 according to the present embodiment includes, as the display element 20c, the touch panel 24, the OCA tape 25, an organic light emitting diode panel 28, and a protection sheet 29, and has a device 42 fixed to the OCA tape 25. Note that, a print 22c is formed on the OCA tape 25. A configuration other than the configuration described above is similar to that of the display apparatus 1 of Embodiment 1.

Note that, similarly to the display element 20a of the display apparatus 1 of Embodiment 1 described above, the display element 20c may include the touch panel 24, the polarizer 26, and the like in addition to the OCA tape 25 and the transparent display device 27. [Conclusion]

A display apparatus according to an aspect 1 of the disclosure has a configuration in which the display apparatus is provided in electronic equipment, and includes a display element which faces a screen that allows transmission of light and in which at least one opening that allows transmission of the light from outside, which has passed through the screen, is formed. A device that inputs and outputs information to the electronic equipment is fixed to the display element through a fixing member, which is installed on the display element, so that the device is able to receive the light transmitted through the opening.

According to the aforementioned configuration, since the device is fixed to the display element through the fixing member installed on the display element, an error when the device is installed in the opening is smaller than a conventional case where the device is installed in a substrate or the like which is separate from the display element. That is, in the case where the device is installed in the substrate or the like which is separate from the display element, it is requested to perform positioning twice in total; positioning of the device and the substrate and positioning of the device installed in the substrate and the opening. Thus, the error when the device is installed in the opening may be increased. On the other hand, in a case where the device is installed in the opening through the fixing member as in the aforementioned configuration, the device arid the opening are directly positioned, so that positioning is to be performed only once and the error when the device is installed in the opening is reduced.

In this manner, in a case where the error when the device is installed in the opening is reduced, a size of the opening (print through hole) in the screen by which the light from outside, which has passed through the screen, is radiated to the device is able to be reduced, resulting that design of a display screen is able to be enhanced.

The display apparatus according to an aspect 2 of the disclosure may have a configuration in which a print for positioning the device is formed in the display apparatus, in the aspect 1. According to the aforementioned configuration, the print for positioning that positions the device is formed in the display apparatus. Thereby, the device is able to be directly positioned for the print for positioning the device, thus making it possible to further reduce the error when the device is installed in the display apparatus. As a result, it is possible to further enhance the design of the display screen.

The display apparatus according to an aspect 3 of the disclosure may have a configuration in which the device is a camera module, in the aspect 1 or 2. According to the aforementioned configuration, by bonding the camera module to the display element, it is possible to easily position a lens of a camera and the opening. As a result, the size of the opening is able to be reduced in accordance with a size of an angle of view of the lens of the camera. Then, the opening becomes visually obscure and the design of the display screen is able to be further enhanced.

The display apparatus according to an aspect 4 of the disclosure may have a configuration in which the display element is a liquid crystal display element and the fixing member is provided in a backlight of the display element, in any of the aspects 1 to 3. According to the aforementioned configuration, the liquid crystal display element is able to be used as the display element and the fixing member is able to be provided in the backlight. As a result, the opening formed in the liquid crystal display element is able to be made visually obscure and the design of the display screen is able to be further enhanced.

Electronic equipment according to an aspect 5 of the disclosure has a configuration in which the electronic equipment includes at least one display apparatus. The display apparatus includes a display element which faces a screen that allows transmission of light and in which at least one opening that allows transmission of the light from outside, which has passed through the screen, is formed, and a device that inputs and outputs information to the electronic equipment is fixed to the display element through a fixing member, which is installed on the display element, so that the device is able to receive the light transmitted through the opening. According to the aforementioned configuration, an action effect similar to that of the aspect 1 is exerted.

The disclosure is not limited to each of the embodiments described above, and may be modified in various manners within the scope indicated in the claims and an embodiment achieved by appropriately combining techniques disclosed in each of different embodiments is also encompassed in the technical scope of the disclosure. Further, by combining the techniques disclosed in each of the embodiments, a new technical feature may be formed.

The present disclosure contains subject matter related to that disclosed in Japanese Priority Patent Application JP 2018-148601 filed in the Japan Patent Office on Aug. 7, 2018, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A display apparatus provided in electronic equipment, the display apparatus comprising
a display element which faces a screen that allows transmission of light and in which at least one opening that allows transmission of the light from outside, which has passed through the screen, is formed, wherein
a device that inputs and outputs information to the electronic equipment is fixed to the display element through a fixing member, which is installed on the display element, so that the device is able to receive the light transmitted through the opening. 2. The display apparatus according to claim 1, wherein a print for positioning the device is formed in the display apparatus. 3. The display apparatus according to claim 1, wherein the device is a camera module. 4. The display apparatus according to claim 1, wherein
the display element is a liquid crystal display element, and
the fixing member is provided in a backlight of the display element. 5. Electronic equipment comprising
at least one display apparatus, wherein
the display apparatus includes
a display element which faces a screen that allows transmission of light and in which at least one opening that allows transmission of the light from outside, which has passed through the screen, is formed, and
a device that inputs and outputs information to the electronic equipment is fixed to the display element through a fixing member, which is installed on the display element, so that the device is able to receive the light transmitted through the opening.
